(19) United States
(12) Patent Application Publication
(10) Pub. No.: US 2024/0201299 A1
(43) Pub. Date: Jun. 20, 2024

(54) Parameterizing an Imaging Sequence

(71) Applicant: Siemens Healthcare GmbH, Erlangen (DE)

(72) Inventor: Mario Zeller, Erlangen (DE)

(73) Assignee: Siemens Healthcare GmbH, Erlangen (DE)

(21) Appl. No.: 18/520,935

(22) Filed: Nov. 28, 2023

(30) Foreign Application Priority Data
Dec. 14, 2022 (DE) 10 2022 213 602.0

(51) Int. Cl. G01R 33/54

(52) U.S. Cl. CPC G01R 33/543

(57) ABSTRACT

A method for parameterizing an imaging sequence, including: (a) receiving and/or establishing at least one fixed parameter using a computer unit; and (b) automatically setting at least one further parameter of the imaging sequence using a neural network installed on the computer unit, based on the at least one fixed parameter.

### TECHNICAL FIELD

The disclosure relates to a method for parameterizing an imaging sequence, a computer-readable data storage device, a system for imaging, and a method for training a neural network.

### BACKGROUND

Independent of the grammatical term usage, individuals with male, female, or other gender identities are included within the term.

Methods for imaging, for example, magnetic resonance (MR) methods with magnetic resonance tomography systems, comprise a large number of imaging sequences. Depending upon the need and the problems underlying different measurements, the imaging sequences must often be adapted accordingly, i.e., in particular, parameterized, for example, according to an image contrast that is to be achieved or a desired degree of robustness to the movement of a subject under investigation, in particular, a patient. This is often referred to as protocol development. The protocol development and/or parameterizing is often highly complex. For MR systems, for example, there is usually a large number of possible contrast settings that are dependent upon a large number of body regions that have possibly to be investigated. In addition, there are often strong dependencies on the specific properties of the respective MR system used and the hardware used, for example, dependencies on surface coils that are used, with respectively different receiving channel numbers. Due to these circumstances, a protocol development, for example, for a new system and/or new hardware, is usually time-consuming and requires a considerable amount of knowledge in the art and a certain degree of experience.

While developers of MR systems often have the knowledge necessary therefor, protocol development is nevertheless usually very time-consuming. In addition, particularly with new, little known, or even unknown imaging techniques and/or modifications of known imaging techniques, the relevant dependencies and restrictions are often not well known. Final customers and/or end users of such systems often do not generally have a sufficient level of training to create suitable protocols or to undertake suitable adaptations of protocols.

In the prior art, therefore, pre-prepared workflows that offer limited adaptability, for example, with regard to the slice count, can be provided to users with predetermined adapted parameters. However, more complex dependencies or even new imaging techniques can usually not be taken into account. In addition, the pre-prepared workflows must also first be (time-consumingly) developed.

### SUMMARY

It is, therefore, an object of the present disclosure to provide a possibility with which the parameterization of an imaging sequence can be simplified for a user and can also function as reliably as possible.

According to a first aspect of the disclosure, a method for parameterizing an imaging sequence, in particular, a medical imaging sequence, is provided. The method comprises the following steps:
(a) receiving and/or establishing at least one fixed parameter using a computer unit;
(b) automatically setting at least one further parameter, in particular, all the remaining parameters, of the imaging sequence using a neural network installed on the computer unit, based on the at least one fixed parameter, wherein the neural network is trained to set the at least one further parameter based on the at least one fixed parameter, wherein in the neural network the parameterization is transferred, in particular, into a sentence-like structure.

Optionally, the method can comprise the following step: selecting and fixing at least one parameter by a user as at least one fixed parameter using input into a user interface and transferring the fixed parameter to the computer unit.

This step can be provided, in particular, temporally before step (b) and/or can replace the more general step (a). Alternatively, the at least one fixed parameter can be established automatically, in particular, by means of an algorithm. For example, the at least one fixed parameter can be established using the computer unit or using another unit, in particular, a further computer unit. For example, the at least one fixed parameter can be established based on an evaluation of a localizer scan. For example, an automated algorithm and/or an automated technique can be established dependent upon an object to be examined, for example, dependent upon patient anatomy, from a localizer scan a parameter value that is needed, for example, a coverage that is needed, i.e., in particular, the slice count that is needed, for an MRT procedure. Advantageously, the at least one fixed parameter can consequently optionally be fixed and/or have been fixed by a previously executed algorithm.

The method for parameterizing an image sequence can also be designated, in particular, a method for protocol development. The medical imaging sequence can be, in particular, a magnetic resonance (MR) imaging sequence. The parameter and the further parameter are, in particular, parameters of the imaging sequence. The at least one parameter that is selected by the user and/or is received can be, for example, an object to be examined, such as, for example, a body region to be examined, or an organ of a patient (for example, head or brain) that is to be examined, a scan mode (for example T2-weighted MR scan or a rapid localization scan), a relevant scan variable (for example magnetic field strength of an MR system, or an X-ray dose), a measuring technique (for example a deep learning reconstruction method) and/or a parameter that is to be optimized. In particular, a plurality of parameters can also be selected and/or received by the user and/or established. It is also conceivable that the user selects a majority of the parameters of an imaging sequence and/or the majority of parameters are received, and the further (still undefined) parameters or also only one further parameter are added in step (b). The further parameter(s) is/are in particular parameters that are needed for a complete scan protocol and/or the imaging sequence and possibly further parameters that are useful for the imaging sequence and/or for the performance or monitoring/checking the imaging sequence. The neural network can be trained, in particular, to set automatically, which further parameters still need to be determined. Alternatively or additionally, the computer unit can comprise a predetermined list with parameters that are to be set for a particular imaging sequence, and the computer unit and/or the neural network can be configured to fix further parameters according to the predetermined list.

The user interface can comprise, for example, input means of a computer, in particular, a PC, and/or the (virtual) user interface of an operating program of a medical imaging system. Alternatively or additionally, the user interface can be or comprise, for example, a console of an imaging system. The user interface is connected, in particular, to the computer unit and/or is part of the computer unit. The user interface can be connected via a network, in particular, wirelessly or cable-bound, to the computer unit. The computer unit can be arranged locally at the site of the user interface or remotely from the user interface. The computer unit can be, for example, a computer, a cloud computer, or a server. Alternatively or additionally, the computer unit can be, for example, a control unit of an imaging system. The computer unit comprises, in particular, a trained neural network with which the at least one further parameter is fixed. It can be particularly advantageous to transfer the parameterization into a sentence-like structure, in particular, using a serialization of the parameters. With a sentence-like structure, in particular, a particularly efficient processing by the neural network can be enabled.

The method according to the disclosure can be applied, for example, for MR protocols and/or MR imaging sequences. Furthermore, an application for other imaging modalities can also be provided, in particular, for imaging modalities in which a parameterization can be serialized and/or can be translated into a sentence-like structure. Other imaging modalities for which the method can possibly be applied are, for example, computed tomography, positron emission tomography, ultrasound, and/or medical lasers. Advantageously, it can be enabled with the method according to the disclosure to undertake an adaptation and/or new creation of imaging sequences in an automated manner. In particular, a parameterization can thus also be initiated flexibly by users with relatively little experience and/or knowledge in the art. In addition, a personal time expenditure by a user for parameterizing can thus possibly be significantly reduced so that a lightening of the load on a user can be achieved. The risk of individual operating errors can possibly also be reduced.

According to one aspect, the neural network is a pre-trained neural network for language processing, which has been adapted using training with parameters of imaging sequences for an automatic parameterization. In particular, the neural network for language processing can be trained by means of transfer learning. A neural network for language processing can also be referred to as an NLP (Natural Language Processing) network. Neural networks for language processing can be used, for example, for writing poems, for language translation, or for completing words or sentences in word processing programs. Neural networks for language processing are already known in the prior art and have recently achieved great advances. These advances are enabled, in particular, by using large quantities of freely available texts that can be used for training the neural networks. At the same time, the quantity of training data for protocol development is limited, so the training of the neural network is made more difficult due to the only small quantity of available training data. Advantageously, however, it has been found that a neural network already pre-trained for language processing can be trained to the extent that good results can be achieved with relatively little additional training, i.e., in particular, using less training data than would be needed for a still untrained neural network. Good results herein mean, in particular, that parameters for imaging sequences can be sufficiently reliably and meaningfully enhanced for actual practice. This aspect, therefore, makes use of the fact that well-trained neural networks, i.e., those trained, in particular, with large quantities of training data, exist for language processing and make use of these pre-trained neural networks as a basis for training for parameterizing and thus ultimately for parameterizing imaging sequences. The pre-trained neural network for language processing can be based, for example, upon the transformer architecture known from the prior art (see A. Vaswani et al. “Attention Is All You Need,” arXiv:1706.03762v5 [cs.CL] 6 Dec. 2017), in particular, the GPT-3 model (see T. Brown et al., “Language Models are Few-Shot Learners,” arXiv:2005.14165v4 [cs.CL] 22 Jul. 2020) or the BERT-Modell (“Bidirectional Encoder Representations from Transformers,” see Devlin et al., “BERT: Pre-training of Deep Bidirectional Transformers for Language Understanding,” arXiv:1810.04805v2 [cs.CL] 24 May 2019).

According to one aspect, in an intermediate step, the at least one fixed parameter is transferred by the computer unit into an, in particular, incomplete sentence-like structure. It is then passed to the neural network for setting the at least one further parameter. The sentence-like structure is, in particular, incomplete in that parts in the sentence-like structure that relate to the at least one further parameter are lacking, wherein the neural network enhances the incomplete sentence-like structure and in this manner determines the at least one further parameter. Advantageously, using the use of a sentence-like structure, the meaning of the parameterization can be particularly well grasped by the neural network and completed. This can apply to a particular extent if the neural network is an NLP network that has been trained by means of transfer learning for the supplementing of parameters. In particular, the sentence-like structure can be evaluated by the neural network as a language-like construct. A sentence-like structure can, in particular, be a structure in which the parameters are represented by means of letters, numbers, and punctuation marks. The sentence-like structure can comprise, in particular, a serialization of the parameters. For example, the sentence-like structure can comprise parameter designations linked using connecting symbols to parameter values, wherein different parameters can be separated, in particular, using separating symbols. A linking of the parameter designations with the parameter values can be provided, for example, using equal signs or space characters and/or connecting symbols can be equal signs or space characters. Separating symbols can be, for example, commas, semicolons and/or dashes, and/or minus signs. Space characters can possibly also be used as separating symbols, in particular, if they are not provided as connecting symbols. For example, a sentence-like structure for a T2-weighed turbo-spin-echo protocol can be directed to the head in a 3 tesla system with a 20-channel head coil, 20 slices with a 4 mm slice thickness, echo time TE=90 ms, repetition time TR=5000 ms and GRAPPA factor 2 can be described with the following sentence-like structure:

“body-region=head, field-strength=3, coil=HN20, protocol-path: Vida-XT/head/library/T2, protocol-name=tse_t2_tra_p2, sg.0.size=20, sl_thick=4, te.0=90, tr.0=5000, pat_acc_pe =2, . . . ”

The sentence-like structure is not necessarily reproduced completely here, i.e., further parameters can possibly be added. However, they can be included into the sentence-like structure according to the same principle as the parameters shown. Naturally, different variations of this specific exemplary aspect are possible. For example, the separating symbols (here, commas) can be replaced by other separating symbols (for example, semicolons). The parameter designations can, for example, also be selected to be different.

According to one aspect, the neural network is configured to link the words of the sentence-like structure in the context of the setting of the at least one further parameter with numbers. In particular, an additional method step can be provided in that the neural network transfers the sentence-like structure into numerical values, and/or the words of the sentence-like structure are linked with numbers. The additional step can be provided, in particular, before the neural network sets the at least one parameter. The linking of the words with numerical values can be referred to, in particular, as tokenization. For example, from a sentence-like structure of the type “slices 10, te 90, tr 3000,” a series of numerical values of the type “1, 80, 5, 900, 19, 329” is formed, wherein, in particular, “slices=1,” “10=80,” “te=5” etc., has been linked. An analogue tokenization is known to a person skilled in the art, for example, from T. Brown et al., arXiv:2005.14165v4 [cs.CL] 22 Jul. 2020 in the context of neural networks for language processing. The implementation for a parameterization in the context of this aspect of the disclosure can, in principle, take place analogously thereto.

According to one aspect, the computer unit comprises a database with specified parameter values for the parameters of the imaging sequence with fixed step sizes between the individual parameter values and/or has access to this database, wherein the method further comprises the following step:
(c) following the setting of the at least one further parameter by the neural network: rounding the parameter set by the neural network to the nearest specified parameter value.

This aspect can be advantageous since parameters and/or protocol parameters for imaging sequences can cover very different value ranges. For example, individual parameters can take the two values “on” or “off” or the values “weak,” “medium,” or “strong.” Other parameters, for example, relating to a slice count, echo time, or repetition time, by contrast, can assume continuous or approximately continuous value ranges. In general, the value range and step size of different parameters can differ greatly. A parameter value of the slice count can have values, for example, in the range from 1 to 128 with step sizes of 1. A parameter value of the echo time can have values, for example, in the range from 1 to 300 with a step size of 1 or 10 or in this range. A repetition time can have values, for example, in the range from 1 to 16000 with a step size of 1 or 10 or in this range. The ranges of the parameter values can have gaps, in particular, such that particular parameter value combinations are precluded. For example, it can be provided that parameter values of a slice count can only assume multiples of a slice acceleration factor. This aspect can advantageously make allowance for this problem of different available parameter values. For example, this aspect can be configured such that the parameter values are quantized, that is, are transferred to discrete values (as opposed to a continuous value range). Advantageously, fixed parameter values can, therefore, be restricted and/or corrected to the parameter values that are specified and/or necessitated by the system. It can be provided that parameter values of the at least one further parameter are restricted and/or rounded to respective multiples of a specified step size. For example, parameter values of an echo time can be rounded to a multiple of 10. Alternatively or additionally, it can be provided that parameter values of the at least one further parameter for a first parameter value range are restricted and/or rounded to respective multiples of a first step size and, for a second parameter value range, to respective multiples of a second step size. For example, parameter values of a repetition time for a first range, for example, the range up to 200 can be rounded to multiples of 10 and for a second range, for example, the range above 200, to multiples of 100. It can be provided to restrict a parameter value range and/or a parameter step size of a parameter dependent upon at least one further parameter, in particular, a parameter value range and/or a parameter step size of the further parameter. For example, a parameter such as the slice count with a slice range to be covered, a slice thickness, and a slice spacing in percent can be put into relation, for example, with a relationship such as slice range=slice count x slice thickness x (1+slice spacing). Advantageously, with this aspect, the further parameters and/or the at least one further parameter can be rounded, after the setting using the neural network, to the parameters usable and/or adjustable by the system. For example, if the neural network has fixed an echo time of 100 ms, while on the respective imaging system, in particular, in combination with other parameters that are used, only an echo time of 94 ms or 112 ms is possible, then a rounding to 94 ms can take place. This aspect can be particularly advantageous in combination with the aspect regarding a linking of parameters to numbers, in particular, since herewith a tokenization can be implemented particularly efficiently and/or a neural network that uses a tokenization (and thus, in particular, operates with numerical values) can be combined particularly well with this variant. In particular, with this aspect, the number of the parameter options to be converted into tokens can possibly be greatly reduced, which can have positive results on the number of training data needed and the prediction accuracy.

According to one aspect, the method is restricted by a fixed parameter limit of at least one parameter. Advantageously, the parameter can be restricted, for example, for safety considerations. This can be useful, for example, with medical lasers and/or in the setting of a radiation dose. For example, a threshold value that must not be exceeded can be predetermined. It can be provided that a confirmation dialogue is displayed to a user when the exceeding of a parameter limit has been prevented. The confirmation dialogue can serve as information of the user. Optionally, the confirmation dialogue can give the possibility to the user of deactivating or displacing the parameter limit, at least temporarily, in order to cancel or amend the restriction of the parameter.

According to one aspect, after the fixing of the at least one parameter by the user and/or after the receiving and/or establishing of the at least one fixed parameter, the computer unit fetches at least one parameter as at least one hardware-related parameter from an imaging device that is to be used, wherein the at least one further parameter is set and/or fixed by the neural network based on the at least one fixed parameter and the at least one hardware parameter. Advantageously, using this aspect, restrictions can be taken into account that exist and/or are necessary or useful in light of the hardware used. For example, a user can select fundamental parameters such as the scan region and the general type of scan (for example, the head region, T2-weighted MR scan). Further parameters, for example, a (magnetic) field strength or a coil used, are given by the hardware. Optionally, a hardware-related parameter can be fetched using a preprocessing step, for example, in that an orientation and a slice count that is needed have been established in the preprocessing step by means of AutoAlign and AutoCoverage. The neural network can ultimately enhance the hardware-related parameter(s) with the at least one further parameter and/or with necessary parameters that are lacking. For example, a sentence-like structure of the type “body-region=head, field-strength=3, coil=HN20, orientation=tra, 0.size=30, sl_thick=3,” in which the user has fixed a region (body-region=head) and for which the hardware-related parameters (field-strength=3, coil=HN20, orientation=tra, sg.0.size=30, sl_thick=3) have been added, can be enhanced with further parameters in a sentence-like structure, for example “te.0=90, tr.0=6000, pat_acc_pe=1, . . . ” using the neural network.

According to one aspect, a user fixes the at least one parameter (which is then, in particular, the at least one fixed parameter) in that he selects and amends a parameter from an existing imaging sequence, wherein the neural network sets the at least one further parameter in that it adapts the other parameters of the existing imaging sequence based on the amended parameter, wherein the neural network is trained to adapt the remaining parameters, in particular, based on specified imaging sequences which vary in the at least one parameter. In this aspect, the neural network can function as a type of translation network, a single parameter or a plurality of parameters (for example, a field strength) is selected by the user, and the neural network “translates,” i.e., adapts, the remaining parameters according to the new requirements given thereby. For example, an existing protocol of the type “body-region=head, field-strength=3, coil=HN20, protocol-path: Vida-XT/head/library/T2, protocol-name=tse_t2_tra_p2, orientation=tra, sg.0.size=30, sl_thick=3, te.0=90, tr.0=6000, pat_acc_pe=2, . . . ,” can be amended by a user with regard to some parameters, for example “body-region=head, field-strength=1.5, coil=HN16, orientation=tra” wherein, using the neural network, the further parameters are adapted so that altogether, for example, “body-region=head, field-strength=1.5, coil=HN16, orientation=tra, sg.0.size=20, sl_thick=4, te.0=90, tr.0=5000, pat_acc_pe=1, . . . ” results.

For the training of the neural network, in particular, imaging sequences that differ in the amended parameter are used. For example, as input, an imaging sequence with a field strength of x tesla and as output, an imaging sequence with a field strength of y tesla, preferably in all permutations x, y, can be used. The datasets can preferably be reduced so that only the differences between the amended parameters (for example, field strengths) are trained.

According to one aspect, the parameter fixed, in particular, by the user, is an amended imaging technique in an existing imaging sequence. In particular, the neural network can adapt the other parameters of the imaging sequence to the amended imaging technique. Advantageously, with this aspect, for example, imaging sequences for new imaging techniques such as for example Simultaneous Multi-Slice (SMS), Compressed Sensing (CS), or Deep Learning Reconstructions can be specifically optimized. In the case of SMS, it can be necessary, for example, to take care that the repetition time (TR) for T2-contrast imaging is not selected too low and that a sufficient spacing exists between slices that are to be excited simultaneously. In the case of CS, it can be necessary to adapt regularization factors to body regions, acceleration factors, and coils that are used. In deep learning reconstructions, it can be provided, for example, to rotate a phase encoding, to adapt a phase oversampling, or to amend a reference scan to achieve good and/or better results. For example, an existing imaging sequence

“body-region=head, field-strength=3, coil=HN20, protocol-path: Vida-XT/head/library/T2, protocol-name=tse_t2_tra_p2, sg.0.size=20, sl_thick=4, te.0=90, tr.0=5000, pat_acc_pe =2,” can be adapted in that it is specified that a special deep learning reconstruction method (identified here with the number 8007) is used. The user therefore fixes, for example, the deep learning reconstruction method, which, as a sentence-like structure, can appear as follows:
“advanced_reconstruction_mode=8007.”

With the neural network, for example, an increase of the acceleration factor with a simultaneous increase in the phase oversampling is fixed, for example:

“pat_acc_pe=4, ph_os=80.”

For training the neural network for this aspect, for example, corresponding imaging sequences can be used with and without the respective imaging technique (as input and for balancing the output), paired in each case. Preferably, the imaging sequences are as far as possible similar in other parameters (for example, with regard to contrast, i.e., echo time TE and repetition time TR, field of view, and slice coverage). Preferably, the pairs can be established automatically using analysis of existing protocol trees with regard to the desired parameters.

According to one aspect, the parameter fixed, in particular, by the user, is the task of omitting a precondition that is needed for the execution of an existing imaging sequence, wherein the neural network adapts the parameters of the existing imaging sequence such that the imaging sequence functions without the precondition that is absent. This aspect can be advantageous, for example, if a hardware item or a hardware part necessary for an imaging sequence is not available or (for example, for licensing reasons) may not or cannot be used. Advantageously, therefore, an imaging sequence can be adapted easily so that it can function without the precondition, whereas the characteristics of the imaging sequence can be at least partially maintained. For training the neural network for this aspect, for example, corresponding imaging sequences can be used with and without the respective precondition (as input and for balancing the output), paired in each case. Preferably, the imaging sequences are as similar as possible in other parameters (for example, regarding a contrast, i.e., echo time TE and repetition time TR, field of view, and slice coverage). Preferably, the pairs can be established automatically using analysis of existing protocol trees with regard to the desired precondition.

According to one aspect, the fixed parameter is fixed in that a user specifies that it is to be optimized in a particular manner, for example, by minimizing or maximizing the parameter value, wherein the neural network adapts the at least one further parameter such that the fixed parameter is optimized in the specified manner. The neural network is, in particular, trained to undertake the adaptation similarly to typical and still useful adaptations. For example, in this way, a scan time can be optimized. For example, the user can specify an upper limit or a lower limit for the scan value that is to be optimized. For training the neural network for this aspect, for example, corresponding imaging sequences can be used with non-optimized and optimized parameters (as input and for balancing the output), paired in each case. Preferably, the imaging sequences are as similar as possible in other parameters. Preferably, the pairs suitable for training can be established automatically using analysis of existing protocol trees with regard to the desired parameters to be optimized.

According to one aspect, the user fixes all the parameters with the exception of the designation of the imaging sequence and/or all the parameters with the exception of the designation of the imaging sequence are received or established as fixed parameters using the computer unit, wherein the neural network automatically sets a designation as a further parameter based on the parameters and their effect, wherein the designation contains information regarding the properties of the imaging sequence. For the purpose of this aspect, the designation fixed by the neural network is also to be regarded as a parameter. This aspect can be used to give feedback to a user who effectively wishes to generate a complete protocol independently regarding the effects of this imaging sequence. Advantageously, this aspect can thus have a control function that can give a user reassurance that a desired effect is achieved and/or a warning that the effect of the imaging sequence is not that which should be achieved. For example, the designation can comprise information relating to a scan mode (for example, T2-weighted or T1-weighted for MR scans). If, for example, the user has adapted a T2-weighted MR sequence according to his intentions but has unintentionally converted it by amending the parameters into a T1-weighted MR sequence, then this feedback can notify the user thereof by naming the sequence as T1-weighted.

For training the neural network for this aspect, for example, corresponding imaging sequences can be used without a designation as input and with a designation as output, paired in each case.

A further aspect of the disclosure is a computer program product, which, when it is executed on a computer, causes the computer to carry out the method described herein. All the advantages and features of the method for parameterizing can be conveyed similarly to the computer program and vice versa. For the computer program product and the other corresponding aspects of the disclosure, steps carried out by the user, in particular, step (a) can correspondingly be understood as a passive step. In particular, the computer program product can be designed so that the receiving of a parameter fixed, in particular, by a user is provided.

A further aspect of the disclosure is a computer-readable data storage device, in particular, a non-volatile data storage device on which a computer program is stored which, when it is executed on a computer, causes the computer to carry out the method described herein. All the advantages and features of the method for parameterizing and of the computer program product can be conveyed similarly to the computer-readable data storage device and vice versa.

A further aspect of the disclosure is a system for imaging, in particular, medical imaging, comprising a computer unit, wherein the computer unit is configured to receive at least one parameter of an imaging sequence that is fixed, in particular, by a user, and/or to establish at least one fixed parameter, wherein the imaging sequence comprises a large number of parameters, wherein the computer unit comprises a neural network and is also configured to set at least one further parameter, in particular, all the remaining parameters, of the imaging sequence using the neural network based on the at least one parameter that is fixed, in particular, by the user, wherein and/or in that the neural network is trained to set the at least one further parameter based on the at least one fixed parameter, wherein the computer unit is configured, in particular, to carry out the method as described herein. The system can comprise, in particular, a user interface for inputting the parameter to be fixed by the user. The system can comprise, in particular, a data storage device on which at least one parameterized imaging sequence is stored. All the advantages and features of the method for parameterizing, of the computer program product, and of the computer-readable data storage device can be conveyed similarly to the system for imaging and vice versa. The system can be, in particular, a system for an imaging modality in which a parameterization can be serialized and/or can be transferred into a sentence-like structure. The system can be, for example, an MR system, a computed tomography system, a positron emission tomography system, an ultrasound system, and/or a medical laser system.

A further aspect of the disclosure is a method for training a neural network for parameterizing an imaging sequence, comprising the following steps:
(a) providing a trained neural network for language processing;
(b) providing parameterized imaging sequences comprising different parameter values;
(c) optionally converting the imaging sequences into a sentence-like structure, wherein the sentence-like structure describes the parameter values;
(d) training the neural network for the language processing with the converted imaging sequences.

All the advantages and features of the method for parameterizing, of the computer program product, of the computer-readable data storage device, and of the system for imaging can be conveyed similarly to the method for training a neural network and vice versa. The imaging sequences that exist and/or are already in use can be used as training data. Preferably, for this purpose, for example, complete imaging sequences are amended such that at least one parameter or a plurality of parameters are lacking and/or that individual parameters are amended in order to provide them for the training input data. The output of the neural network can be balanced during the training with the complete image sequences. For example, imaging sequences can be used which each differ in at least one parameter, for example, a field strength, in order to simulate a fixing of the at least one parameter by a user. The datasets of the imaging sequences can optionally be so reduced that only the differences between the at least one parameter are trained. Advantageously, due to the circumstance that the neural network is already pre-trained for the language processing, a smaller quantity of training data can be sufficient so that the neural network delivers reliable and useful results after the retraining. For example, a few hundred datasets of imaging sequences can be sufficient.

A further aspect of the disclosure is the use of a neural network for the language processing for a parameterizing of an imaging sequence, wherein the neural network has been retrained for the automatic parameterizing of an imaging sequence. All the advantages and features of the method for parameterizing, of the computer program product, of the computer-readable data storage device, of the system for imaging, and of the method for training a neural network can be transferred similarly to the use of a neural network and vice versa.

All the aspects described herein can be combined where not explicitly stated otherwise.

### BRIEF DESCRIPTION OF THE DRAWINGS

Aspects will now be described referring to the accompanying drawings.

FIG. 1 shows a flow diagram of a method for parameterizing an imaging sequence according to an aspect of the disclosure,

FIG. 2 shows a flow diagram of a method for parameterizing an imaging sequence according to a further aspect of the disclosure,

FIG. 3 shows a method for training a neural network for parameterizing an imaging sequence according to an aspect of the disclosure, and

FIG. 4 shows a system according to an aspect of the disclosure.

### DETAILED DESCRIPTION

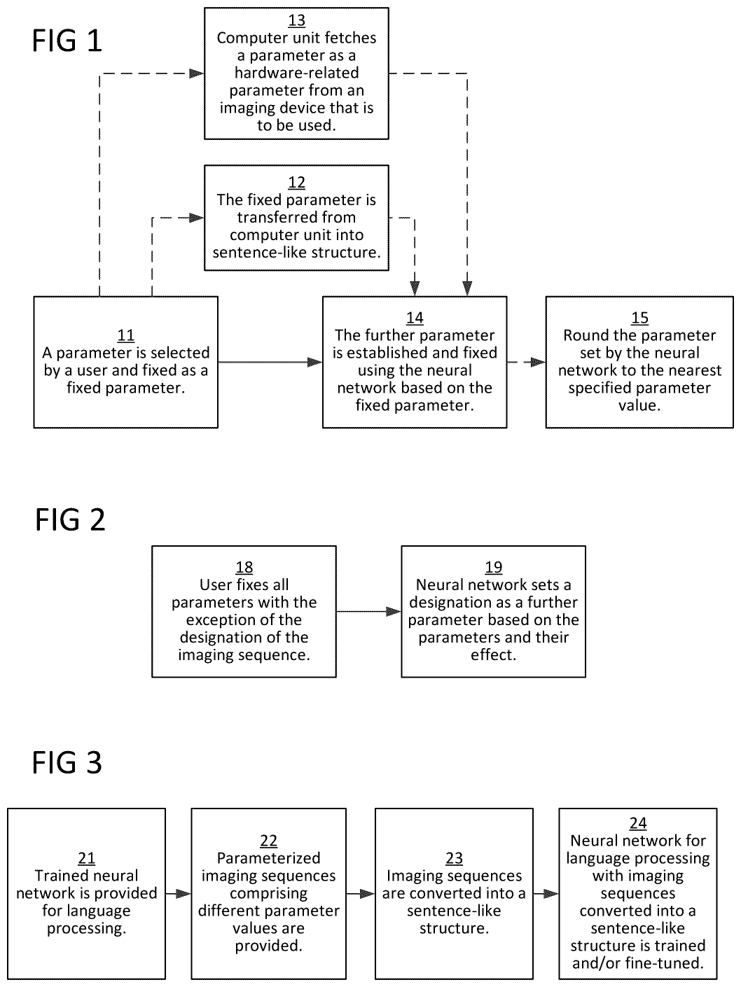

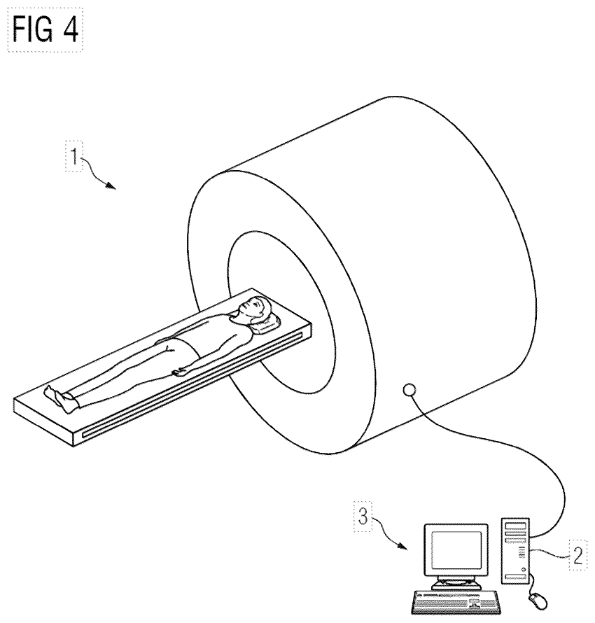

FIG. 1 shows a flow diagram of a method for parameterizing an imaging sequence according to an aspect of the disclosure. In a first step 11, at least one parameter is selected by a user and is fixed as at least one fixed parameter. This can take place, in particular, using input into a user interface 3, whereby, in particular, a computer unit 2 can receive the at least one fixed parameter. In one variant, the user can fix the at least one parameter in that he selects and amends a parameter from an existing imaging sequence. Additionally, or alternatively, the parameter set by the user can be an amended imaging technique in an existing imaging sequence. Additionally, or alternatively, the parameter fixed by the user can be the task of omitting a precondition that is needed for the execution of an existing imaging sequence.

In an optional step 12, it can be provided that the at least one fixed parameter is transferred from the computer unit 2 into a sentence-like structure. The sentence-like structure can, in particular, be incomplete so that parts of the sentence-like structure are lacking. The neural network is trained to set the at least one further parameter of the imaging sequence based on the at least one fixed parameter. The at least one further parameter can correspond, in particular, to the lacking parts of the sentence-like structure. The neural network can preferably be a pre-trained neural network for language processing which has been adapted using training with parameters of imaging sequences for an automatic parameterization. Additionally, or alternatively, the user can specify that a parameter is to be optimized in a particular manner, for example, by minimizing the parameter value.

Additionally or alternatively, it can be provided in a further optional step 13 that after the fixing of the at least one parameter by the user, the computer unit fetches at least one parameter as at least one hardware-related parameter from an imaging device that is to be used.

In a subsequent step 14, the at least one further parameter, preferably all the remaining parameters of the imaging sequence, is accordingly established and fixed using the neural network based on the at least one fixed parameter. Optionally, the neural network can also be taken into account when setting the at least one further parameter in addition to the at least one hardware-related parameter as a parameter that has already been set. In a variant, the neural network can set the at least one further parameter in that it adapts the remaining parameters of the existing imaging sequence based on the amended parameter. If the user has specified the task of omitting a precondition, the neural network can adapt the parameters of the existing imaging sequence such that the imaging sequence functions without the precondition that is not present. If the user has specified that a parameter should be optimized wherein the fixed parameter is fixed in that a user specifies that it is to be optimized in a particular manner, for example, by minimizing the parameter value, then the neural network adapts at least one further parameter in such a way that the parameter fixed by the user is optimized in the specified manner.

In a further optional step 15, it can be provided to round the parameter set by the neural network to the nearest specified parameter value. For this purpose, the computer unit can comprise a database with specified parameter values for the parameters of the imaging sequence with fixed step sizes between the individual parameter values or can have access to this database.

FIG. 2 shows a flow diagram of a method for parameterizing an imaging sequence according to a further aspect of the disclosure. Herein, in a first step 18, the user fixes all the parameters with the exception of the designation of the imaging sequence, and in a next step 19, the neural network sets a designation as a further parameter based on the parameters and their effect. Therein, the designation contains information regarding the properties of the imaging sequence. In a first step 21, firstly a trained neural network is provided for language processing. That is, the neural network is trained to carry out language processing, for example, the completion of texts. In a further step 22, parameterized imaging sequences comprising different parameter values are provided. In a further step 23, the imaging sequences are converted into a sentence-like structure. Finally, in a yet further step 24, the neural network for language processing with the imaging sequences converted into a sentence-like structure is trained and/or fine-tuned. The training can take place, for example, by means of unsupervised learning in that the neural network is fine-tuned for language processing with a large number of existing protocols and/or imaging sequences. Alternatively, or additionally, training with protocols having the same name and different parameter values of a parameter, for example, field strengths, is conceivable. Herein, for example, a parameter value x can be used as input and a parameter value y as output, in particular, in all permutations x, y. The datasets can also be reduced so that only the differences between the parameter values are trained. Alternatively or additionally, corresponding protocols and/or imaging sequences with and without a respective imaging technique but otherwise basic parameters as similar as possible can be used as input and output. This variant can optionally be adapted in that the boundary condition is not the imaging technique but rather the difference in a parameter to be optimized so that an adaptation of the imaging sequence can be trained for optimizing a specified parameter. The creation of a designation of the imaging sequence can be trained, for example, in that a set of protocol parameters is used as input, and a protocol name is used as output.

FIG. 4 shows a system 1 for imaging according to an aspect of the disclosure. The system 1 comprises a computer unit 2 and a user interface 3. The computer unit 2 is configured to carry out the automatic steps of the method according to the disclosure described herein. The system is further configured to enable the user input regarding the setting of at least one parameter via the user interface 3.

Although the disclosure has been illustrated and described in detail with the preferred exemplary aspect, the disclosure is not restricted by the examples disclosed, and other variations can be derived therefrom by a person skilled in the art without departing from the protective scope of the disclosure.

1. A computer-implemented method for parameterizing an imaging sequence of a magnetic resonance system, the method comprising:
(a) receiving and/or establishing at least one fixed parameter using a computer unit; and
(b) automatically setting at least one further parameter of the imaging sequence using a neural network installed on the computer unit, based on the at least one fixed parameter,
wherein the neural network is trained to set the at least one further parameter based on the at least one fixed parameter, and wherein in the neural network the parameterization is transferred into a sentence-like structure.

2. The computer-implemented method as claimed in claim 1,
wherein the neural network is a pre-trained neural network for language processing which has been adapted using training with parameters of imaging sequences for an automatic parameterization.

3. The computer-implemented method as claimed in claim 1,
wherein in an intermediate step, the at least one fixed parameter is transferred by the computer unit into an incomplete sentence-like structure and is then passed to the neural network for setting the at least one further parameter,
wherein the sentence-like structure is incomplete in that parts in the sentence-like structure which relate to the at least one further parameter are lacking, and
wherein the neural network enhances the incomplete sentence-like structure and in this manner determines the at least one further parameter.

4. The computer-implemented method as claimed in claim 1,
wherein the computer unit comprises a database with specified parameter values for the parameters of the imaging sequence with fixed step sizes between individual parameter values and/or has access to this database, and
wherein the method further comprises:
(c) following the setting of the at least one further parameter by the neural network, rounding the parameter set by the neural network to the nearest specified parameter value.

5. The computer-implemented method as claimed in claim 1,
wherein after receiving and/or establishing the at least one fixed parameter, the computer unit fetches at least one parameter from an imaging device that is to be used as at least one hardware-related parameter, and
wherein using the neural network, the at least one further parameter is set based on the at least one fixed parameter and the at least one hardware-related parameter.

6. The computer-implemented method as claimed in claim 1,
wherein a user fixes the at least one parameter by selecting and amending a parameter from an existing imaging sequence,
wherein the neural network sets the at least one further parameter in that it adapts the remaining parameters of the existing imaging sequence based on the amended parameter, and
wherein the neural network is trained to adapt the remaining parameters.

7. The computer-implemented method as claimed in claim 1,
wherein the fixed parameter is an amended imaging technique in an existing imaging sequence.

8. The computer-implemented method as claimed in claim 1,
wherein the fixed parameter is a task of omitting a precondition that is needed for execution of an existing imaging sequence, and
wherein the neural network adapts the parameters of the existing imaging sequence such that the imaging sequence functions without the precondition that is not present.

9. The computer-implemented method as claimed in claim 1,
wherein the fixed parameter is fixed in that a user specifies that it is to be optimized in a specified manner, and
wherein the neural network adapts the at least one further parameter in such a way that the fixed parameter is optimized in the specified manner.

10. The computer-implemented method as claimed in claim 1,
wherein a user fixes all the parameters with exception of a designation of the imaging sequence and/or wherein all the parameters with the exception of the designation of the imaging sequence are received or established as fixed parameters using the computer unit,
wherein the neural network automatically sets a designation as a further parameter based on the parameters and their effect, and
wherein the designation includes information regarding properties of the imaging sequence.

11. The computer-implemented method as claimed in claim 1, automatically setting at least all the remaining parameters of the imaging sequence using the neural network installed on the computer unit, based on the at least one fixed parameter.

12. The computer-implemented method as claimed in claim 1, wherein the neural network is trained to adapt the remaining parameters based on specified imaging sequences which vary in the at least one parameter.

13. The computer-implemented method as claimed in claim 1,
wherein the fixed parameter is fixed in that a user specifies that it is to be optimized by minimizing the parameter value.

14. A non-transitory computer-readable data storage device on which a computer program is stored which, when it is executed on a computer, causes the computer to carry out the method as claimed in claim 1.

15. A magnetic resonance system for imaging, comprising:
a computer unit operable to receive at least one fixed parameter of an imaging sequence and/or to establish at least one fixed parameter, wherein the imaging sequence includes a number of parameters,
wherein the computer unit comprises a neural network and is also operable to set at least one further parameter of the imaging sequence using the neural network based on the at least one fixed parameter,
wherein the neural network is trained to set the at least one further parameter based on the at least one fixed parameter, and
wherein the computer unit is configured to carry out the method as claimed in claim 1.

16. The system as claimed in claim 15, wherein the computer unit is operable to set all the remaining parameters of the imaging sequence using the neural network based on the at least one fixed parameter.

17. A computer-implemented method for training a neural network for parameterizing an imaging sequence of a magnetic resonance system, comprising:
(a) a computer unit providing a trained neural network for language processing;
(b) the computer unit providing parameterized imaging sequences comprising different parameter values;
(c) the computer unit converting the imaging sequences into a sentence-like structure, wherein the sentence-like structure describes the parameter values; and
(d) the computer unit training the neural network for the language processing with the converted imaging sequences.
